(19) United States
(12) Patent Application Publication
(10) Pub. No.: US 2024/0411221 A1
(43) Pub. Date: Dec. 12, 2024

(54) PHOTOMASK SET, DESIGN METHOD THEREOF, AND MANUFACTURING METHOD OF PHOTORESIST PATTERN

(71) Applicant: United Microelectronics Corp., Hsinchu (TW)

(72) Inventors: Chun-Yi Chang, Taichung City (TW); Chien-Hao Chen, Tainan City (TW)

(73) Assignee: United Microelectronics Corp., Hsinchu (TW)

(21) Appl. No.: 18/346,279

(22) Filed: Jul. 3, 2023

(30) Foreign Application Priority Data
Jun. 7, 2023 (TW) 112121324

(51) Int. Cl. G03F 1/42; G03F 1/44; G03F 1/68; G03F 7/00

(52) U.S. Cl. CPC G03F 1/42; G03F 1/44; G03F 1/68; G03F 7/70633

(57) ABSTRACT

A photomask set including a first photomask and a second photomask is provided. The first photomask includes a first pattern. The first pattern includes a first main portion and a first stitching portion connected to each other. The first stitching portion includes a first matching portion and a first overlapping portion connected to each other. The second photomask includes a second pattern. The second pattern includes a second main portion and a second stitching portion connected to each other. The second stitching portion includes a second matching portion and a second overlapping portion connected to each other. After the first photomask is aligned with the second photomask, the first matching portion matches the second matching portion, the first overlapping portion overlaps the second pattern, and the second overlapping portion overlaps the first pattern.

### CROSS-REFERENCE TO RELATED APPLICATION

This application claims the priority benefit of Taiwan application serial no. 112121324, filed on Jun. 7, 2023. The entirety of the above-mentioned patent application is hereby incorporated by reference herein and made a part of this specification.

### BACKGROUND

### Technical Field

The invention relates to a photomask structure, a design method thereof, and a semiconductor process, and particularly relates to a photomask set, a design method thereof, and a manufacturing method of a photoresist pattern.

### Description of Related Art

In the semiconductor process, the lithography technology plays an important role. In the lithography process of some products, it is necessary to perform multiple exposure processes on the photoresist layer to obtain the desired photoresist pattern. In addition, when multiple exposure processes are performed on the photoresist layer, some areas of the photoresist layer will be exposed repeatedly for pattern stitching. However, since some areas of the photoresist layer will be repeatedly exposed, the critical dimension (CD) of the photoresist pattern will be enlarged, and the side-lobe effect will be enhanced to cause the damage to the photoresist pattern.

### SUMMARY

The invention provides a photomask set, a design method thereof, and a manufacturing method of a photoresist pattern, which can make the critical dimension of the photoresist pattern obtained by the lithography process meet the expectation and can effectively reduce the side-lobe effect.

The invention provides a photomask set, which includes a first photomask and a second photomask. The first photomask includes a first pattern. The first pattern includes a first main portion and a first stitching portion connected to each other. The first stitching portion includes a first matching portion and a first overlapping portion connected to each other. The second photomask includes a second pattern. The second pattern includes a second main portion and a second stitching portion connected to each other. The second stitching portion includes a second matching portion and a second overlapping portion connected to each other. After the first photomask is aligned with the second photomask, the first matching portion matches the second matching portion, the first overlapping portion overlaps the second pattern, and the second overlapping portion overlaps the first pattern.

According to an embodiment of the invention, in the photomask set, the first pattern may be the light-transmitting pattern of the first photomask, and the second pattern may be the light-transmitting pattern of the second photomask.

According to an embodiment of the invention, in the photomask set, the maximum width of the first stitching portion may be less than the maximum width of the first main portion.

According to an embodiment of the invention, in the photomask set, the maximum width of the second stitching portion may be less than the maximum width of the second main portion.

According to an embodiment of the invention, in the photomask set, after the first photomask is aligned with the second photomask, the first overlapping portion may extend toward the second pattern.

According to an embodiment of the invention, in the photomask set, after the first photomask is aligned with the second photomask, the second overlapping portion may extend toward the first pattern.

According to an embodiment of the invention, in the photomask set, the shape of the first pattern may be the same as the shape of the second pattern.

According to an embodiment of the invention, in the photomask set, the shape of the first pattern may be different from the shape of the second pattern.

According to an embodiment of the invention, in the photomask set, the first matching portion may have a protrusion, and the second matching portion may have a recess. After the first photomask is aligned with the second photomask, the protrusion may fill the recess.

According to an embodiment of the invention, in the photomask set, the first matching portion may have a recess, and the second matching portion may have a protrusion. After the first photomask is aligned with the second photomask, the protrusion may fill the recess.

The invention provides a design method of a photomask set, which includes the following steps. A target pattern is provided. A first pattern of a first photomask and a second pattern of a second photomask are designed according to the target pattern. The first pattern includes a first main portion and a first stitching portion connected to each other. The first stitching portion includes a first matching portion and a first overlapping portion connected to each other. The second pattern includes a second main portion and a second stitching portion connected to each other. The second stitching portion includes a second matching portion and a second overlapping portion connected to each other. After the first photomask is aligned with the second photomask, the first matching portion matches the second matching portion, the first overlapping portion overlaps the second pattern, and the second overlapping portion overlaps the first pattern.

According to an embodiment of the invention, in the design method of the photomask set, the first pattern may be the light-transmitting pattern of the first photomask, and the second pattern may be the light-transmitting pattern of the second photomask.

According to an embodiment of the invention, in the design method of the photomask set, the maximum width of the first stitching portion may be less than the maximum width of the first main portion.

According to an embodiment of the invention, in the design method of the photomask set, the maximum width of the second stitching portion may be less than the maximum width of the second main portion.

According to an embodiment of the invention, in the design method of the photomask set, after the first photomask is aligned with the second photomask, the first overlapping portion may extend toward the second pattern, and the second overlapping portion may extend toward the first pattern.

According to an embodiment of the invention, in the design method of the photomask set, the shape of the first pattern may be the same as the shape of the second pattern.

According to an embodiment of the invention, in the design method of the photomask set, the shape of the first pattern may be different from the shape of the second pattern.

According to an embodiment of the invention, in the design method of the photomask set, the first matching portion may have a protrusion, and the second matching portion may have a recess. After the first photomask is aligned with the second photomask, the protrusion may fill the recess.

According to an embodiment of the invention, in the design method of the photomask set, the first matching portion may have a recess, and the second matching portion may have a protrusion. After the first photomask is aligned with the second photomask, the protrusion may fill the recess.

The invention provides a manufacturing method of a photoresist pattern, which includes the following steps. A photoresist layer is formed. The above photomask set is provided. A first exposure process is performed on the photoresist layer by using the first photomask. A second exposure process is performed on the photoresist layer by using the second photomask. A development process is performed on the photoresist layer to form a photoresist pattern.

Based on the above description, in the photomask set, the design method thereof, and the manufacturing method of the photoresist pattern according to the invention, after the first photomask is aligned with the second photomask, the first matching portion of the first photomask matches the second matching portion of the second photomask, the first overlapping portion of the first photomask overlaps the second pattern of the second photomask, and the second overlapping portion of the second photomask overlaps the first pattern of the first photomask. Therefore, when the lithography process is performed by using the above photomask set, the critical dimension of the photoresist pattern can meet the expectation, and the side-lobe effect can be effectively reduced.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1C are schematic top views of a design method of a photomask set according to some embodiments of the invention.

FIG. 2A is a schematic top view according to other embodiments of the present invention when a first photomask and a second photomask in a photomask set are aligned with each other.

FIG. 2B is a schematic top view when the first photomask and the second photomask in the photomask set of FIG. 2A are not aligned with each other.

FIG. 3A is a schematic top view according to other embodiments of the present invention when a first photomask and a second photomask in a photomask set are aligned with each other.

FIG. 3B is a schematic top view when the first photomask and the second photomask in the photomask set of FIG. 3A are not aligned with each other.

FIG. 4A is a schematic top view according to other embodiments of the present invention when a first photomask and a second photomask in a photomask set are aligned with each other.

FIG. 4B is a schematic top view when the first photomask and the second photomask in the photomask set of FIG. 4A are not aligned with each other.

FIG. 5A to FIG. 5C are cross-sectional views of a manufacturing process of a photoresist pattern according to some embodiments of the invention.

FIG. 6 is a schematic top view of the photoresist pattern in FIG. 5C.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

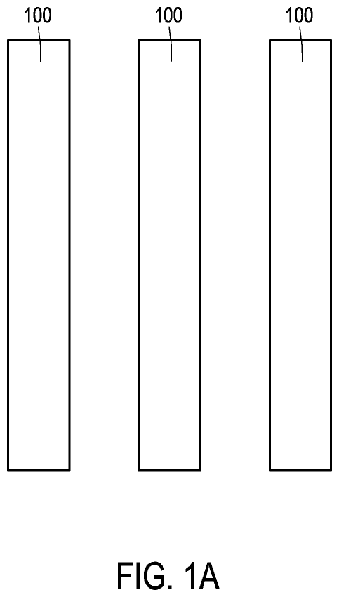

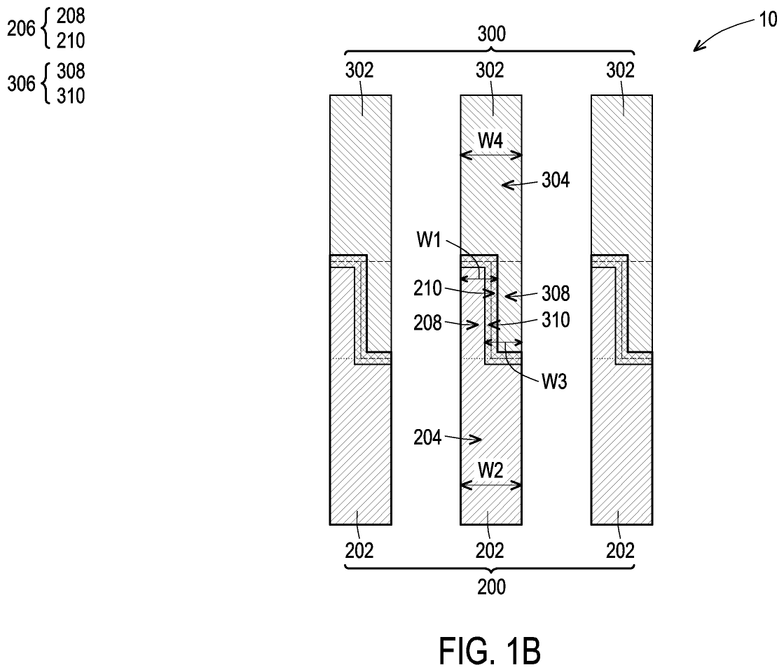

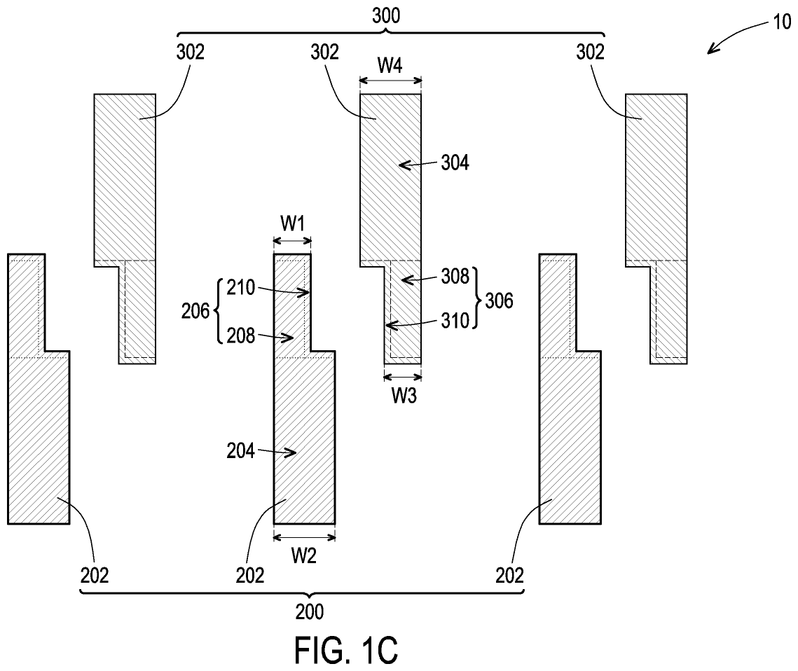

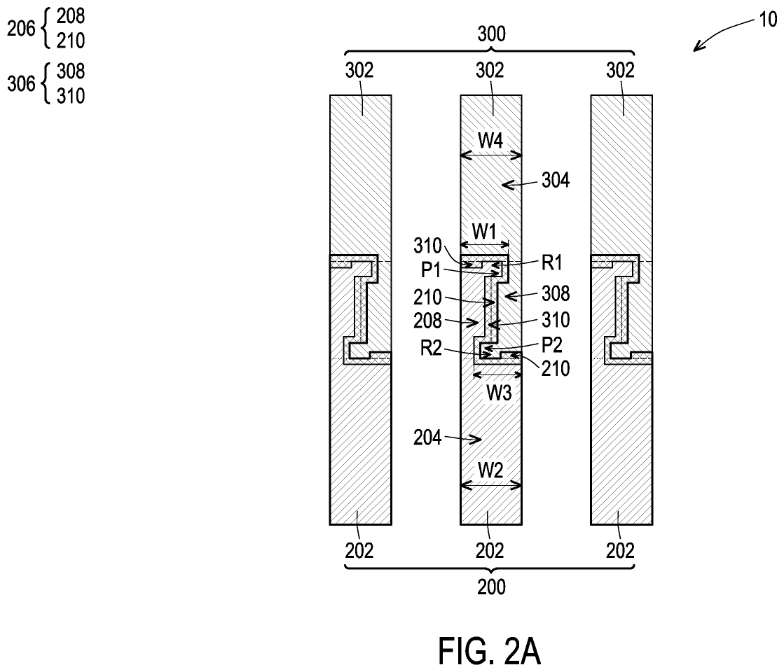

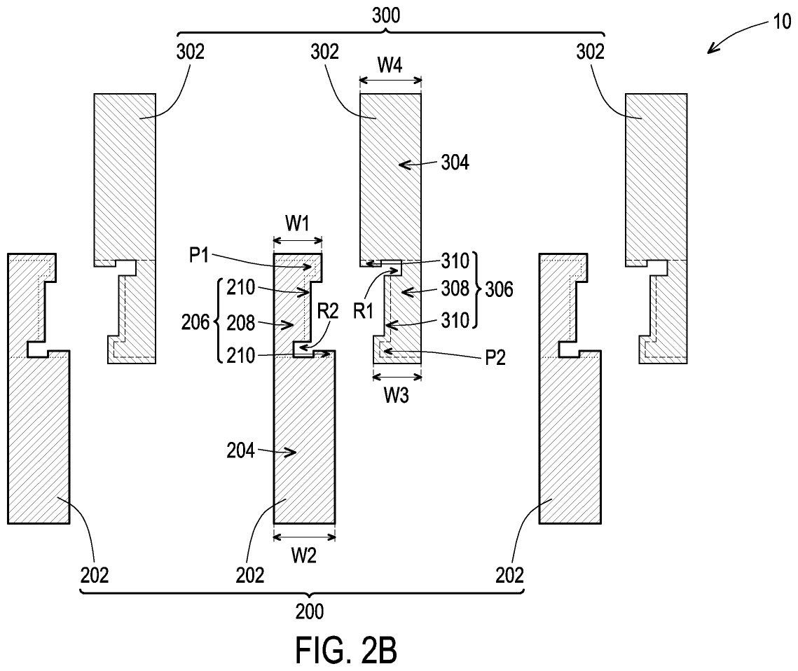

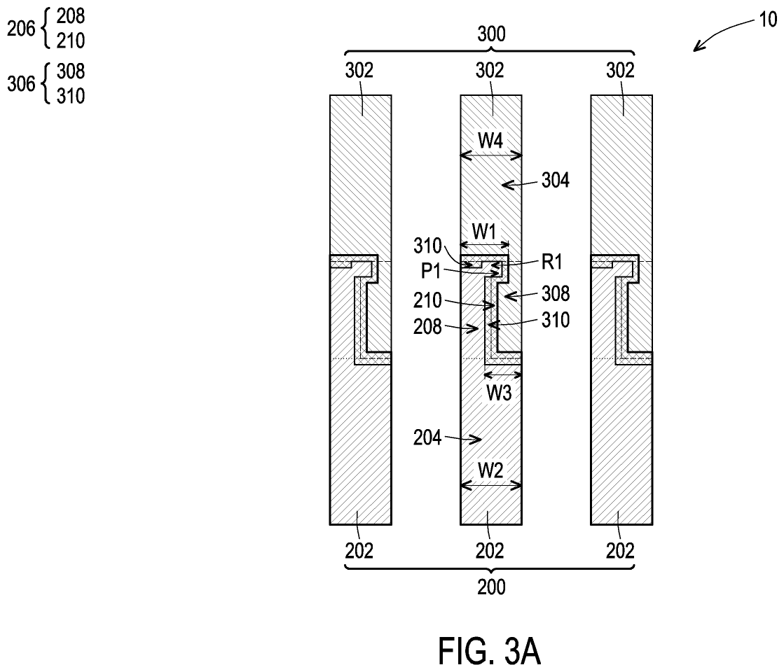

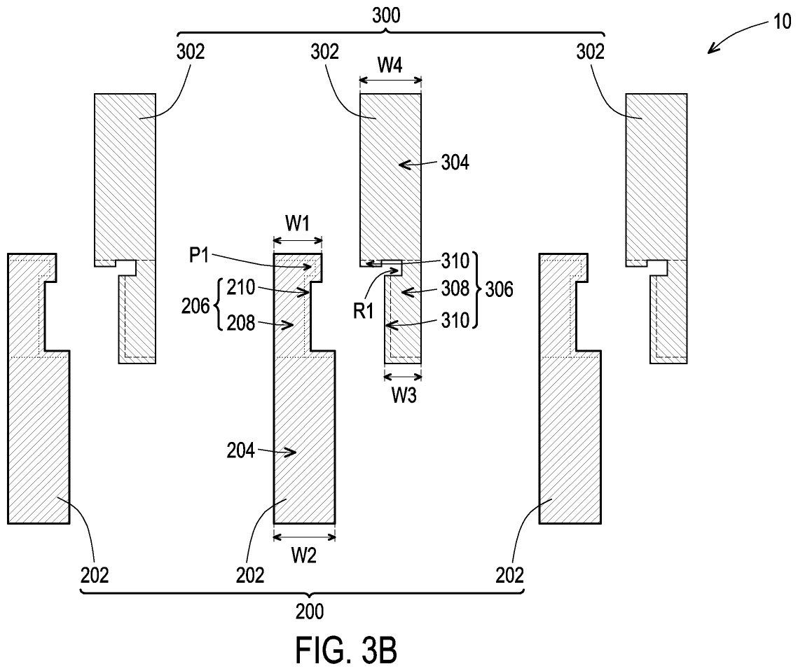

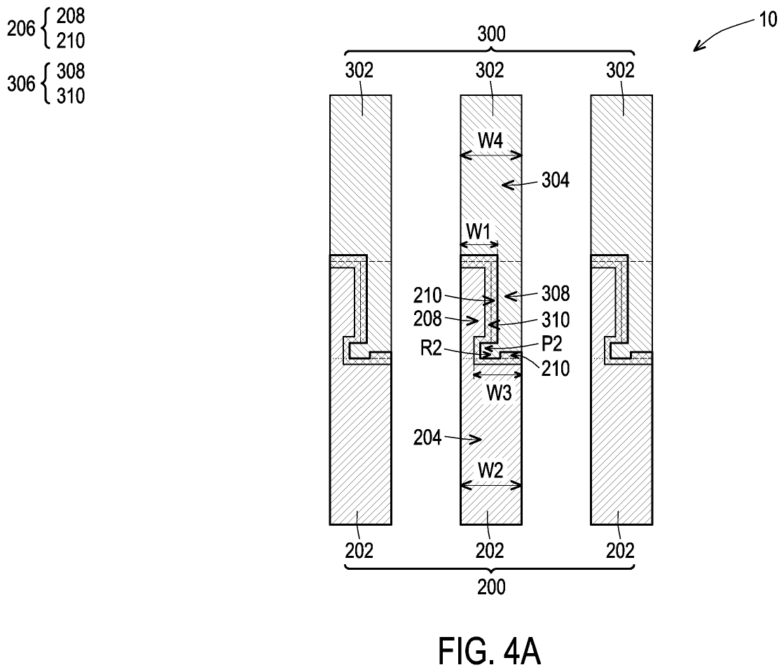

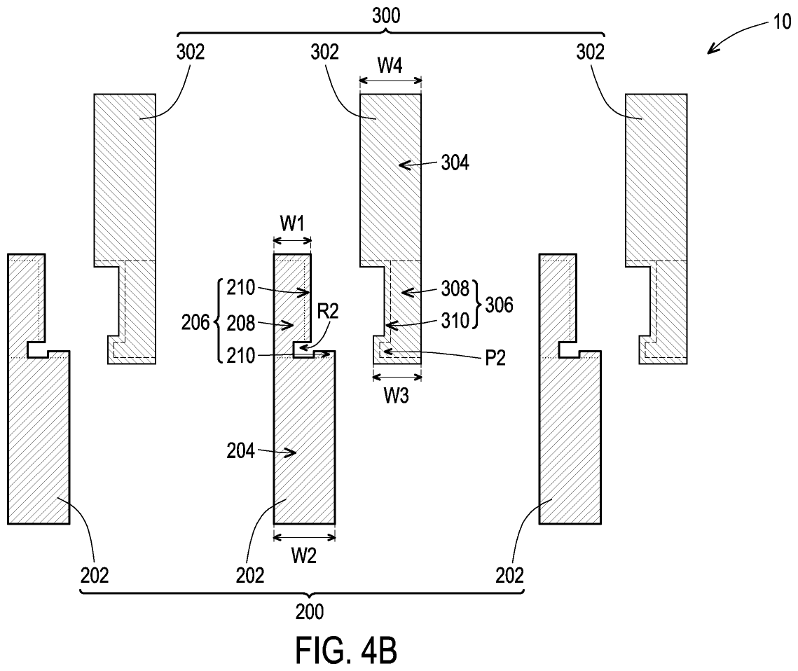

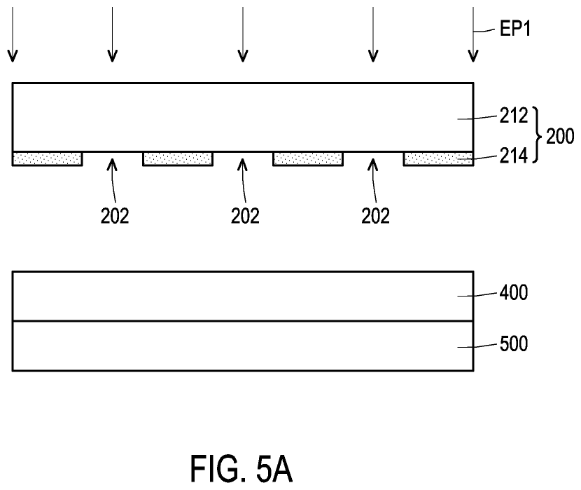

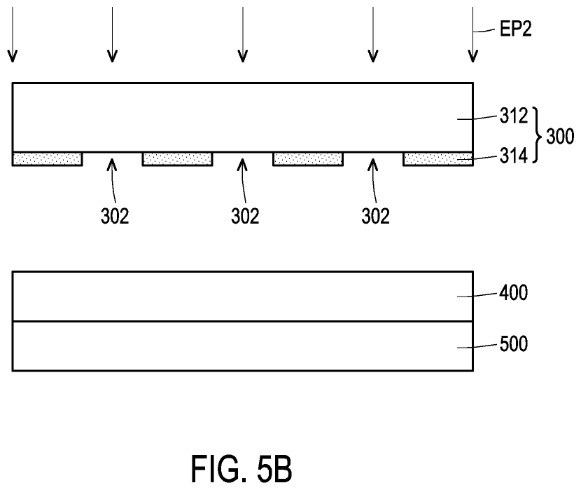

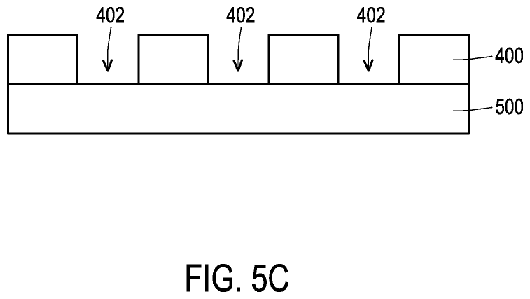

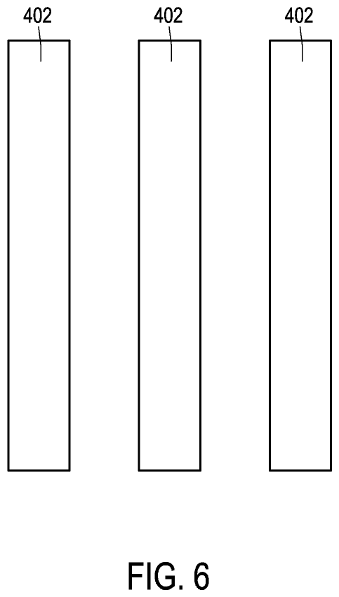

FIG. 1A to FIG. 1C are schematic top views of a design method of a photomask set according to some embodiments of the invention. FIG. 1B is a schematic top view when the first photomask and the second photomask in the photomask set are aligned with each other. FIG. 1C is a schematic top view when the first photomask and the second photomask in the photomask set are not aligned with each other. FIG. 2A is a schematic top view according to other embodiments of the present invention when a first photomask and a second photomask in a photomask set are aligned with each other. FIG. 2B is a schematic top view when the first photomask and the second photomask in the photomask set of FIG. 2A are not aligned with each other. FIG. 3A is a schematic top view according to other embodiments of the present invention when a first photomask and a second photomask in a photomask set are aligned with each other. FIG. 3B is a schematic top view when the first photomask and the second photomask in the photomask set of FIG. 3A are not aligned with each other. FIG. 4A is a schematic top view according to other embodiments of the present invention when a first photomask and a second photomask in a photomask set are aligned with each other. FIG. 4B is a schematic top view when the first photomask and the second photomask in the photomask set of FIG. 4A are not aligned with each other. FIG. 5A to FIG. 5C are cross-sectional views of a manufacturing process of a photoresist pattern according to some embodiments of the invention. FIG. 6 is a schematic top view of the photoresist pattern in FIG. 5C.

Referring to FIG. 1A, a target pattern 100 is provided. In some embodiments, the target pattern 100 may be a pattern intended to be transferred to the photoresist layer. In some embodiments, the target pattern 100 may be a trench pattern. In addition, the number of target patterns 100 is not limited to the number in the figure. As long as the number of target patterns 100 is one or more, it falls within the scope of the invention.

Referring to FIG. 1B and FIG. 1C, a first pattern 202 of a first photomask 200 and a second pattern 302 of a second photomask 300 are designed according to the target pattern 100. In some embodiments, as shown in FIG. 1B, after the first photomask 200 is aligned with the second photomask 300, the pattern formed by the first pattern 202 and the second pattern 302 may be the same as the target pattern 100. In some embodiments, the first pattern 202 may be the light-transmitting pattern of the first photomask 200, and the second pattern 302 may be the light-transmitting pattern of the second photomask 300. In addition, the number of the first patterns 202 and the number of the second patterns 302 are not limited to the number in the figure. As long as the number of the first patterns 202 and the number of the second patterns 302 are respectively one or more, it falls within the scope of the invention.

By the method above, a photomask set 10 may be designed. The photomask set 10 includes the first photomask 200 and the second photomask 300. The first photomask 200 includes the first pattern 202. The first pattern 202 includes a first main portion 204 and a first stitching portion 206 connected to each other. In some embodiments, the maximum width W1 of the first stitching portion 206 may be less than the maximum width W2 of the first main portion 204. The first stitching portion 206 includes a first matching portion 208 and a first overlapping portion 210 connected to each other.

The second photomask 300 includes the second pattern 302. The second pattern 302 includes a second main portion 304 and a second stitching portion 306 connected to each other. In some embodiments, the maximum width W3 of the second stitching portion 306 may be less than the maximum width W4 of the second main portion 304. The second stitching portion 306 includes a second matching portion 308 and a second overlapping portion 310 connected to each other.

As shown in FIG. 1B, after the first photomask 200 is aligned with the second photomask 300, the first matching portion 208 matches the second matching portion 308, the first overlapping portion 210 overlaps the second pattern 302, and the second overlapping portion 310 overlaps the first pattern 202. In some embodiments, as shown in FIG. 1B, after the first photomask 200 is aligned with the second photomask 300, the first overlapping portion 210 may extend toward the second pattern 302. In some embodiments, as shown in FIG. 1B, after the first photomask 200 is aligned with the second photomask 300, the second overlapping portion 310 may extend toward the first pattern 202.

In other embodiments, as shown in FIG. 2A and FIG. 2B, the first matching portion 208 may have a protrusion P1, and the second matching portion 308 may have a recess R1. As shown in FIG. 2A, after the first photomask 200 is aligned with the second photomask 300, the protrusion P1 may fill the recess R1. As shown in FIG. 2A, after the first photomask 200 is aligned with the second photomask 300, the first matching portion 208 may fill up the recess R1. In addition, as shown in FIG. 2A and FIG. 2B, the first matching portion 208 may have a recess R2, and the second matching portion 308 may have a protrusion P2. As shown in FIG. 2A, after the first photomask 200 is aligned with the second photomask 300, the protrusion P2 may fill the recess R2. As shown in FIG. 2A, after the first photomask 200 is aligned with the second photomask 300, the second matching portion 308 may fill up the recess R2.

In other embodiments, in the photomask set 10 of FIG. 3A and FIG. 3B, the protrusion P2 and recess R2 in the photomask set 10 of FIG. 2A and FIG. 2B may be omitted. In other embodiments, in the photomask set 10 of FIG. 4A and FIG. 4B, the protrusion Pl and recess R1 in the photomask set 10 of FIG. 2A and FIG. 2B may be omitted.

Furthermore, since the light intensity distribution of the first stitching portion 206 and the light intensity distribution of the second stitching portion 306 are not necessarily uniform, the protrusion (e.g., protrusion P1 and/or protrusion P2) and recess (e.g., recess R1 and/or recess R2) may be designed by using optical proximity correction (OPC) to balance the exposure intensity.

In some embodiments, as shown in FIG. 1B, FIG. 1C, FIG. 2A, and FIG. 2B, the shape of the first pattern 202 may be the same as the shape of the second pattern 302. In other embodiments, as shown in FIG. 3A, FIG. 3B, FIG. 4A, and FIG. 4B, the shape of the first pattern 202 may be different from the shape of the second pattern 302. In addition, in FIG. 1B, FIG. 1C, FIG. 2A, FIG. 2B, FIG. 3A, FIG. 3B, FIG. 4A, and FIG. 4B, the same or similar components are denoted by the same reference symbols, and the description thereof is omitted.

Hereinafter, a method for forming a photoresist pattern by using the above photomask set 10 will be described with reference to FIG. 1B, FIG. 1C, FIG. 2A, FIG. 2B, FIG. 3A, FIG. 3B, FIG. 4A, FIG. 4B, FIG. 5A to FIG. 5C, and FIG. 6.

Referring to FIG. 5A, a photoresist layer 400 is formed. In some embodiments, the photoresist layer 400 may be formed on a material layer 500. The material layer 500 may be an object to be patterned. In some embodiments, the material of the photoresist layer 400 is, for example, a positive photoresist material. In some embodiments, the method of forming the photoresist layer 400 is, for example, a spin coating method.

The photomask set 10 is provided. In some embodiments, the photomask set 10 may be the photomask set 10 shown in FIG. 1B and FIG. 1C, the photomask set 10 shown in FIG. 2A and FIG. 2B, the photomask set 10 shown in FIG. 3A and FIG. 3B, or the photomask set 10 shown in FIG. 4A and FIG. 4B. The photomask set 10 includes the first photomask 200 and the second photomask 300. In addition, the details of the photomask set 10 may refer to the description of the above embodiments, and the description thereof is not repeated here.

A first exposure process EP1 is performed on the photoresist layer 400 by using the first photomask 200. In some embodiments, the first photomask 200 may include a substrate 212 and a light shielding layer 214. In some embodiments, the substrate 212 is, for example, a transparent substrate. In some embodiments, the material of the substrate 212 is, for example, quartz. The light shielding layer 214 is disposed on the substrate 212. In some embodiments, the material of the light shielding layer 214 is, for example, an opaque material (e.g., chrome) or a phase shift material (e.g., molybdenum silicide).

The first photomask 200 includes the first pattern 202. In some embodiments, the first pattern 202 may be the light-transmitting pattern of the first photomask 200. For example, the first pattern 202 may be the pattern of the trench in the light shielding layer 214.

Referring to FIG. 5B, a second exposure process EP2 is performed on the photoresist layer 400 by using the second photomask 300. In some embodiments, the second photomask 300 may include a substrate 312 and a light shielding layer 314. In some embodiments, the substrate 312 is, for example, a transparent substrate. In some embodiments, the material of the substrate 312 is, for example, quartz. The light shielding layer 314 is disposed on the substrate 312. In some embodiments, the material of the light shielding layer 314 is, for example, an opaque material (e.g., chrome) or a phase shift material (e.g., molybdenum silicide).

The second photomask 300 includes the second pattern 302. In some embodiments, the second pattern 302 may be the light-transmitting pattern of the second photomask 300. For example, the second pattern 302 may be the pattern of the trench in the light shielding layer 314.

Referring to FIG. 5C and FIG. 6, a developing process is performed on the photoresist layer 400 to form a photoresist pattern 402. In some embodiments, the photoresist pattern 402 may be the pattern of the trench in the photoresist layer 400. In addition, as shown in FIG. 1 and FIG. 6, the shape of the photoresist pattern 402 (FIG. 6) obtained by performing the lithography process by using the above photomask set 10 may be similar to the shape of the target pattern 100 (FIG. 1).

Based on the above embodiments, in the photomask set 10, the design method thereof, and the manufacturing method of the photoresist pattern 402, after the first photomask 200 is aligned with the second photomask 300, the first matching portion 208 of the first photomask 200 matches the second matching portion 308 of the second photomask 300, the first overlapping portion 210 of the first photomask 200 overlaps the second pattern 302 of the second photomask 300, and the second overlapping portion 310 of the second photomask 300 overlaps the first pattern 202 of the first photomask 200. Therefore, when the lithography process is performed by using the above photomask set 10, the critical dimension of the photoresist pattern 402 can meet the expectation, and the side-lobe effect can be effectively reduced.

In summary, in the photomask set, the design method thereof, and the manufacturing method of the photoresist pattern of the aforementioned embodiments, when the lithography process is performed by using the photomask set of the aforementioned embodiments, the critical dimension of the photoresist pattern can meet the expectation, and the side-lobe effect can be effectively reduced.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A photomask set, comprising:
a first photomask comprising a first pattern, wherein the first pattern comprises a first main portion and a first stitching portion connected to each other, and the first stitching portion comprises a first matching portion and a first overlapping portion connected to each other; and
a second photomask comprising a second pattern, wherein the second pattern comprises a second main portion and a second stitching portion connected to each other, the second stitching portion comprises a second matching portion and a second overlapping portion connected to each other, and
after the first photomask is aligned with the second photomask, the first matching portion matches the second matching portion, the first overlapping portion overlaps the second pattern, and the second overlapping portion overlaps the first pattern.

2. The photomask set according to claim 1, wherein
the first pattern is a light-transmitting pattern of the first photomask, and
the second pattern is a light-transmitting pattern of the second photomask.

3. The photomask set according to claim 1, wherein a maximum width of the first stitching portion is less than a maximum width of the first main portion.

4. The photomask set according to claim 1, wherein a maximum width of the second stitching portion is less than a maximum width of the second main portion.

5. The photomask set according to claim 1, wherein after the first photomask is aligned with the second photomask, the first overlapping portion extends toward the second pattern.

6. The photomask set according to claim 1, wherein after the first photomask is aligned with the second photomask, the second overlapping portion extends toward the first pattern.

7. The photomask set according to claim 1, wherein a shape of the first pattern is the same as a shape of the second pattern.

8. The photomask set according to claim 1, wherein a shape of the first pattern is different from a shape of the second pattern.

9. The photomask set according to claim 1, wherein
the first matching portion has a protrusion,
the second matching portion has a recess, and
after the first photomask is aligned with the second photomask, the protrusion fills the recess.

10. The photomask set according to claim 1, wherein
the first matching portion has a recess,
the second matching portion has a protrusion, and
after the first photomask is aligned with the second photomask, the protrusion fills the recess.

11. A design method of a photomask set, comprising:
providing a target pattern; and
designing a first pattern of a first photomask and a second pattern of a second photomask according to the target pattern, wherein
the first pattern comprises a first main portion and a first stitching portion connected to each other,
the first stitching portion comprises a first matching portion and a first overlapping portion connected to each other;
the second pattern comprises a second main portion and a second stitching portion connected to each other,
the second stitching portion comprises a second matching portion and a second overlapping portion connected to each other,
after the first photomask is aligned with the second photomask, the first matching portion matches the second matching portion, the first overlapping portion overlaps the second pattern, and the second overlapping portion overlaps the first pattern.

12. The design method of the photomask set according to claim 11, wherein
the first pattern is a light-transmitting pattern of the first photomask, and
the second pattern is a light-transmitting pattern of the second photomask.

13. The design method of the photomask set according to claim 11, wherein a maximum width of the first stitching portion is less than a maximum width of the first main portion.

14. The design method of the photomask set according to claim 11, wherein a maximum width of the second stitching portion is less than a maximum width of the second main portion.

15. The design method of the photomask set according to claim 11, wherein after the first photomask is aligned with the second photomask, the first overlapping portion extends toward the second pattern, and the second overlapping portion extends toward the first pattern.

16. The design method of the photomask set according to claim 11, wherein a shape of the first pattern is the same as a shape of the second pattern.

17. The design method of the photomask set according to claim 11, wherein a shape of the first pattern is different from a shape of the second pattern.

18. The design method of the photomask set according to claim 11, wherein
the first matching portion has a protrusion,
the second matching portion has a recess, and
after the first photomask is aligned with the second photomask, the protrusion fills the recess.

19. The design method of the photomask set according to claim 11, wherein
the first matching portion has a recess,
the second matching portion has a protrusion, and
after the first photomask is aligned with the second photomask, the protrusion fills the recess.

20. A manufacturing method of a photoresist pattern, comprising:
forming a photoresist layer,
providing the photomask set according to claim 1;
performing a first exposure process on the photoresist layer by using the first photomask;
performing a second exposure process on the photoresist layer by using the second photomask; and
performing a development process on the photoresist layer to form a photoresist pattern.
